(19) United States
(12) Patent Application Publication
(10) Pub. No.: US 2023/0397394 A1
(43) Pub. Date: Dec. 7, 2023

(54) METHOD FOR PRODUCING MEMORY DEVICE USING PILLAR-SHAPED SEMICONDUCTOR ELEMENTS

(71) Applicant: Unisantis Electronics Singapore Pte. Ltd., Singapore (SG)

(72) Inventors: Nozomu HARADA, Tokyo (JP); Koji SAKUI, Tokyo (JP)

(21) Appl. No.: 18/234,996

(22) Filed: Aug. 17, 2023

Related U.S. Application Data
(63) Continuation-in-part of application No. 17/478,282, filed on Sep. 17, 2021, now Pat. No. 11,776,620.
Application No. 17/478,282 is a continuation of application No. PCT/JP2020/048952, filed on Dec. 25, 2020.
Application No. PCT/JP2020/048952 is a continuation-in-part of application No. PCT/JP2021/007044, filed on Feb. 25, 2021.

(51) Int. Cl. H10B 12/00; G11C 11/404; G11C 11/4096

(52) U.S. Cl. CPC H10B 12/20; G11C 11/404; G11C 11/4096

(57) ABSTRACT

Provided is dynamic flash memory for performing data write, read, and erase operations by controlling a voltage applied to each of a source line, a plate line, word lines, and bit lines. The memory is formed by forming on a substrate a first N⁺ layer, which connects to the source line, and second N⁺ layers, which connect to the bit lines, at opposite ends of Si pillars standing is the upright position along the vertical direction; and forming a SiO₂ layer, which is located between a first TiN layer surrounding a first gate HfO₂ layer surrounding the lower portion of the Si pillars, is continuous around the Si pillars, and connects to the plate line, and second TiN layers surrounding a second gate HfO₂ layer surrounding the upper portion of the Si pillars and respectively connecting to the word lines, by oxidizing a doped semiconductor layer or conductor layer.

### CROSS REFERENCE TO RELATED APPLICATIONS

The present application is a continuation-in-part application of U.S. Application Ser. No. 17/478,282 filed Sep. 17, 2021, which is a continuation application of PCT/JP2020/048952 having an international filing date of Dec. 25, 2020. This application is also a continuation-in-part application of PCT/JP2021/007044, filed Feb. 25, 2021, the entire contents of each of which are incorporated herein by reference.

### BACKGROUND OF THE INVENTION

### Field of the Invention

The present invention relates to a method for producing a memory device using pillar-shaped semiconductor elements.

### Description of the Related Art

In recent years, a higher degree of integration and higher performance of memory devices have been demanded in the development of the LSI (Large Scale Integration) technology.

In a common planar MOS transistor, a channel extends in the horizontal direction along the upper surface of a semiconductor substrate. In contrast, a channel of a SGT extends in a direction perpendicular to the upper surface of a semiconductor substrate (for example, see Japanese Patent Laid-Open No. 2-188966 and Hiroshi Takata, Kazumasa Sunouchi, Naoko Okabe, Akihiro Nitayama, Kausuhiko Hieda, Fumio Horiguchi and Fujio Masuoka: IEEE Transaction on Electron Devices, Vol. 38, No.3, pp.573-578 (1991)). Therefore, when SGTs are used, the density of a semiconductor device can be increased more than when planar MOS transistors are used. Using such SGTs as selection transistors can achieve a high degree of integration of, for example, DRAM (Dynamic Random Access Memory) with a capacitor connected thereto (for example, see H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)), PCM (Phase Change Memory) with a variable resistance element connected thereto (for example, see H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No 12, December, pp.2201-2227 (2010)), RRAM (Resistive Random Access Memory; for example, see K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3 V,” IEDM (2007)), and MRAM (Magneto-resistive Random Access Memory) whose resistance is changed by changing the direction of a magnetic spin using a current (for example, see W. Kang, L. Zhang, J. Klein, Y. Zhanq, D. Ravelosona, and W. Zhao: “Reconfigurable Code sign of STT-MRAM Under Process Variations in Deeply Scaled Technology,” IEEE Transaction on Electron Devices, pp.1-9 (2015)). There is also known a capacitorless DRAM memory cell including a single MOS transistor (see M. G. Ertosum, K. Lim, C. Park, C. Oh, P. Kirsch, and. K. C. Saraswat: “Novel Capacitorless Single-Transistor Charge-Trap DRAM (1T CT DRAM) Utilizing Electron,” IEEE Electron Device Letter, Vol. 31, No.5, p.405-407 (2010) and J. Wan, L. Rojer, A. Zaslavsky, and S. Critoloveanu: “A Compact Capacitor-Less High-Speed DRAM Using Field Effect-Controlled Charge Regeneration,” Electron Device Letters, Vol. 35, No.2, pp.179-181 (2012)), for example. The present application relates to dynamic flash memory that can be formed with only a MOS transistor and without a variable resistance element or a capacitor.

FIGS. 9A to 9D illustrate a data write operation for the aforementioned capacitorless DRAM memory cell including a single MOS transistor, FIGS. 10A and 10B illustrate problems with the operation thereof, and FIGS. 11A to 11C illustrate a read operation (see C. Wan, L. Rojer, A. Zaslaysky, and S. Critoioveanu: “A Compact Capacitor-Less High-Speed DRAM Using Field Effect-Controlled Charge Regeneration,” Electron Device Letters, Vol. 35, No.2, pp.179-181 (2012), T. Ohsawa, K. Fujita, T. Higashi, Y. Iwata, T. Kajiyama, Y. Asao, and K. Sunouchi: “Memory design using a one-transistor gain cell on SOI,” IEEE JSSC, vol.37, No.11, pp1510-1522 (2002), T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006), and E. Yoshida and T. Tanaka: “A Design of a Capacitorless IT-DRAM Cell Using Gate-induced Drain-Leakage (GIDL) Current for Low-Power and High-Speed Embedded Memory,” IEEE IEDM (2003)).

FIGS. 9A to 9D illustrate a data write operation for the DRAM memory cell. FIG. 9A illustrates a “1” written state. Herein, the memory cell includes a source N⁺ layer 103 (hereinafter, a semiconductor region containing a high concentration of donor impurities shall be referred to as an “layer”) connecting to a source line SL and a drain N⁺ layer 104 connecting to a bit line BL, each formed in a SOI substrate 100; a gate conductive layer 105 connecting to a word line WL; and a floating body 102 of a MOS transistor 110a. The DRAM memory cell does not include a capacitor, and is formed with a single MOS transistor 110a. It should be noted that the floating body 102 is in contact with a SiO₂ layer 101 of the SOI substrate immediately below the floating body 102. When “1” is written to such a memory cell including a single MOS transistor 110a, the MOS transistor 110a is operated in the saturation region. That is, a channel 107 for electrons extending from the source N⁺ layer 103 has a pinch-off point 108, and thus does not reach the drain N⁺ layer 104 connecting to the bit line. When the MOS transistor 110a is operated while each of the bit line BL connected to the drain N⁺ layer 104 and the word line WL connected to the gate conductive layer 105 is set at a high voltage and the gate voltage is set at a level of about ½ that of the drain voltage, the intensity of an electric field becomes maximum at the pinch-off point 108 around the drain N⁺ layer 104. Consequently, accelerated electrons flowing from the source N⁺ layer 103 to The drain N⁺ layer 104 collide with Si lattices, and electron-hole pairs are generated due to the kinetic energy lost during the collision. Most of the generated electrons (not illustrated) reach the drain N⁺ layer 104. Meanwhile, only some of the electrons that are very hot reach the gate conductive layer 105 beyond a gate oxide film 109. In addition, holes 106 generated at the same time charge the floating body 102. In such a case, since the floating body 102 is p-type Si, the generated holes contribute to increasing the majority carriers. When the floating body 102 is filled with the generated holes 106 and the voltage of the floating body 102 becomes higher than that of the source N⁺ layer 103, specifically, Vb or greater, the generated holes are further released to the source N⁺ layer 103. Herein, Vb is the built-in voltage of a P-N junction between the source N⁺ layer 103 and the floating body 102 as the P-layer, and is about 0.7 V. FIG. 9B illustrates a view in which the floating body 102 is saturated with and charged with the generated holes 106.

Next, an operation of writing “0” to the memory cell 110 will be described with reference to FIG. 9C. With respect to a common selected word line WL, there randomly exist memory cells 110a to which “1” is written and memory cells 110b to which “0” is written. FIG. 9C. illustrates a view in which the state of the memory cell 110 changes from the “1” written state to the “0” written state. When “0” is written, the bit line BL is set at a negative bias voltage so that a P-N junction between the drain N⁺ layer 104 and the floating body 102 as the P-layer is forward-biased. Consequently, the holes 106, which have been generated in the floating body 102 in advance in the previous cycle, flow to the drain N⁺ layer 104 connected to the bit line BL. When the write operation is complete, two states of the memory cells are obtained that include the memory cells 110a filled with the generated holes 106 (FIG. 9B) and the memory cells 110b from which the generated holes have been discharged (FIG. 9C). The potential of the floating body 102 in the memory cell 110a filled with the holes 106 is higher than that of the floating body 102 without holes generated therein. Thus, the threshold voltage of the memory cell 110a is lower than the threshold voltage of the memory cell 110b. FIG. 9D illustrates such a state.

Next, problems with the operation of such a memory cell including a single MOS transistor will be described with reference to FIGS. 10A and 10B. As illustrated in FIG. 10A, the capacitance C_{FB} of the floating body 102 is equal to the sum of the capacitance C_{WL} between the gate connecting to the word line and the floating body 102, the junction capacitance C_{SL} of the P-N junction between the source N⁺ layer 103 connecting to the source line and the floating body 102, and the junction capacitance C_{BL} of the P-N junction between the drain N⁺ layer 104 connecting to the bit line and the floating body 102, and is represented as follows.

C_{FB}=C_{WL}+C_{BL}+C_{SL} (2)

Thus, when the voltage V_{WL} of the word line oscillates during writing, the voltage of the floating body 102 as a storage node (i.e., a node) of the memory cell is also influenced. FIG. 10B illustrates such a state. When the voltage V_{WL} of the word line rises from 0 V to V_{ProgWL} during writing, the voltage V_{FB} of the floating body 102 rises from the voltage V_{FB1} in the initial state before the voltage of the word line has changed to V_{FB2} due to capacitive coupling with the word line. The amount of change in the voltage ΔV_{FB} is represented as follows.

$$\begin{matrix}{ΔV}_{FB} = {V}_{FB 2} - {V}_{FB 1} \\ = {C}_{WL} / ( {C}_{WL} + {C}_{BL} + {C}_{SL} ) \times {V}_{FrogWL}\end{matrix} \qquad ( 3 )$$

Herein, β, which is referred to as a coupling ratio, is represented as follows.

β=C_{WL}/(C_{WL}+C_{BL}+C_{SL} (4)

In such a memory cell, the contribution rate of C_{WL} is high, and, for example, C_{WL}:C_{BL}:C_{SL}=8:1:1. In such a case, β=0.8. When the voltage of the word line has changed from 5 V during writing to 0 V at the completion of the writing, for example, the floating body 102 receives oscillation noise with 5 V×β=4 V due to the capacitive coupling between the word line and the floating body 102. Therefore, there has been a problem in that a sufficient margin cannot be provided for the potential difference between the potentials of the floating body when “1”is written thereto and “0” is written thereto.

FIGS. 11A to 11C illustrate a data read operation. Specifically, FIG. 11A illustrates a “1” written state and FIG. 11B illustrates a “0” written state. However, in practice, even when Vb has been written to the floating body 102 during writing of “1,” the floating body 102 is negative-biased once the voltage of the word line returns to 0 V at the completion of the writing. When “0” is written, the floating body 102 is negative-biased further deeply. Thus, as illustrated in FIG. 11C, it would be impossible to provide a sufficient margin for the potential difference between when “1” is written and when “0” is written. Such a small operation margin has been a big problem with the present DRAM memory cell. In addition, it is also demanded to increase the density of such a DRAM memory cell.

### SUMMARY OF THE INVENTION

In a memory device using SGTs, each capacitorless single-transistor DRAM (i.e., a gain cell) involves strong capacitive coupling between a word line and a body of the SGT in a floating state, and thus has a problem in that when the potential of the word line is oscillated during data reading or data writing, the oscillation is directly transmitted as noise to the body of the SGT. Consequently, problems, such as erroneous reading and erroneous rewriting of memory data, occur, making it difficult to put the capacitorless single-transistor DRAM (i.e., the gain cell) into practical use. In addition to solving such problems, it is also necessary to increase the density of the DRAM memory cell.

To solve the foregoing problems, a method for producing a memory device using pillar-shaped semiconductor elements according to the present invention is a method for producing a memory device, the memory device being configured to perform each of a data write operation, a data read operation, and a data erase operation by controlling a voltage applied to each of a first gate conductor layer, a second gate conductor layer, a first impurity region, and a second impurity region, the method including forming a first semiconductor pillar standing in an upright position on a substrate along a vertical direction; forming a first gate insulating layer surrounding a side face of the first semiconductor pillar; forming a first conductor layer surrounding a side face of the first gate insulating layer; forming a first oxidized insulating layer on the first conductor layer through oxidation; forming a second gate insulating layer on the side face of the first semiconductor pillar at a level above the first oxidized insulating layer in the vertical direction; forming the second gate conductor layer surrounding a side face of the second gate insulating layer; forming the first gate conductor layer including the first conductor layer as a base material after forming the first conductor layer and before or after forming the first oxidized insulating layer; forming the first impurity region connecting to a bottom portion of the first semiconductor pillar before or after forming the first semiconductor pillar; and forming the second impurity region on top of the semiconductor pillar before or after forming the first semiconductor pillar (first invention).

In the foregoing first invention, the method further includes selectively forming a first material layer of a conductor or a semiconductor on the first gate conductor layer; and oxidizing a surface layer or an entirety of the first material layer to form the first oxidized insulating layer (second invention).

In the foregoing first invention, the method further includes oxidizing a surface layer of the first conductor layer to form the first oxidized insulating layer (third invention).

In the foregoing first invention, the method further includes forming the second gate insulating layer continuously on the side face of the first semiconductor pillar and on the first oxidized insulating layer in the vertical direction (fourth invention).

In the foregoing second invention, the method further includes exposing the side face of the first semiconductor pillar at a level above the first material layer after forming the first oxidized insulating layer; and oxidizing the exposed side face of the semiconductor pillar to form the second gate insulating layer (fifth invention).

In the foregoing second invention, the method further includes exposing the side face of the first semiconductor pillar at a level above the first gate insulating layer; and oxidizing the first material layer to form the first oxidized insulating layer, and also oxidizing the exposed side face of the semiconductor pillar to form a second oxidized insulating layer, in which the second oxidized insulating layer serves as the second gate insulating layer (sixth invention).

In the foregoing sixth invention, the method further includes forming a first insulating layer surrounding a side face of the second oxidized insulating layer and continuous with an upper surface of the first oxidized insulating layer after forming the second oxidized insulating layer, in which the second oxidized insulating layer and the first insulating layer form the second gate insulating layer (seventh invention).

In the foregoing first invention, the method further includes leaving the first gate insulating layer at a level above the first oxidized insulating layer in the vertical direction, and then forming the second gate conductor layer, in which the first gate insulating layer left at the level above the first oxidized insulating layer serves as the second gate insulating layer (eighth invention).

In the foregoing first invention, the method further includes forming a second conductor layer surrounding the second gate insulating layer after forming the second gate insulating layer, the second conductor layer having an upper surface position located around a lower end of the second impurity region; selectively forming a second material layer of a conductor or a semiconductor on the second conductor layer; and oxidizing a surface layer or an entirety of the second material layer to form a second oxidized insulating layer (ninth invention).

In the foregoing seventh invention, the method further includes oxidizing a surface layer of the second conductor layer to form the second oxidized insulating layer (tenth invention).

In the foregoing first invention, the first material layer is formed of silicon germanium (SiGe) (eleventh invention).

In the foregoing first invention, a wire connecting to the first impurity region is a source line, a wire connecting to the second impurity region is a bit line, one of a wire connecting to the first gate conductor layer or a wire connecting to the second gate conductor layer is formed as a word line, and another is formed as a first drive control line, and each of the data erase operation, the data read operation, and the data write operation is performed with a voltage applied to each of the source line, the bit line, the first drive control line, and the word line (twelfth invention).

In the foregoing first invention, the first gate conductor layer, the first semiconductor pillar, and the second gate conductor layer are formed such that a first gate capacitance between the first gate conductor layer and the first semiconductor pillar is larger than a second gate capacitance between the second gate conductor layer and the first semiconductor pillar (thirteenth invention).

In the foregoing first invention, the method further includes, after forming the second gate conductor layer, forming a third gate insulating layer surrounding the side face of the first semiconductor pillar, and forming a second oxidized insulating layer on the second gate conductor layer; and forming a third gate conductor layer surrounding the third gate insulating layer (fifteenth invention).

In the foregoing fifteenth invention, the first gate conductor layer, the second gate conductor layer, and the third gate conductor layer have the same length in the vertical direction (sixteenth invention).

### BRIEF DESCRIPTION OF THE DRAWINGS

FIG. 1 is a view illustrating the structure of a memory device including SGTs according to a first embodiment.

FIGS. 2A, 2B and 2C are views for illustrating the mechanism of a data erase operation for the memory device including the SGTs according to the first embodiment.

FIGS. 3A, 3B and 3C are views for illustrating the mechanism of a data write operation for the memory device including the SGTs according to the first embodiment.

FIGS. 4AA, 4AB and 4AC are views for illustrating the mechanism of a data read operation for the memory device including the SGTs according to the first embodiment.

FIGS. 4BA, 4BB, 4BC and 4BD are views for illustrating the mechanism of a data read operation for the memory device including the SGTs according to the first embodiment.

FIGS. 5AA, 5AB and 5AC are views for illustrating a method for producing the memory device including the SGTs according to the first embodiment.

FIGS. 5BA, 5BB and 5BC are views for illustrating the method for producing the memory device including the SGTs according to the first embodiment.

FIGS. 5CA, 5CB and 5CC are views for illustrating the method for producing the memory device including the SGTs according to the first embodiment.

FIGS. 5DA, 5DB and 5DC are views for illustrating the method for producing the memory device including the SGTs according to the first embodiment.

FIGS. 5EA, 5EB and 5EC are views for illustrating the method for producing the memory device including the SGTs according to the first embodiment.

FIGS. 5FA, 5FB and 5FC are views for illustrating the method for producing the memory device including the SGTs according to the first embodiment.

FIGS. 5GA, 5GB and 5GC are views for illustrating the method for producing the memory device including the SGTs according to the first embodiment.

FIGS. 5HA, 5HB, 5HC and 5HD are views for illustrating the method for producing the memory device including the SGTs according to the first embodiment.

FIGS. 5IA, 5IB, 5IC and 5ID are views for illustrating the method for producing the memory device including the SGTs according to the first embodiment.

FIGS. 5JA, 5JB and 5JC are views for illustrating the method for producing the memory device including the SGTs according to the first embodiment.

FIG. 5K is a schematic structural view of the memory device including the SGTs according to the first embodiment.

FIGS. 6A, 6B and 6C are a views for illustrating a method for producing a memory device including SGTs according to a second embodiment.

FIGS. 7AA, 7AB and 7AC are views for illustrating a method for producing a memory device including SGTs according to a third embodiment.

FIGS. 7BA, 7BB and 7BC are views for illustrating the method for producing the memory device including the SGTs according to the third embodiment.

FTGS. 7CA, 7CB and 7CC are views for illustrating the method for producing the memory device including the SGTs according to the third embodiment.

FIGS. 8AA, 8AB and 8AC are views for illustrating a method for producing a memory device including SGTs according to a fourth embodiment.

FIGS. 8BA, 8BB and 8BC are views for illustrating the method for producing the memory device including the SGTs according to the fourth embodiment.

FIGS. 9A, 9B, 9C and 9D are views for illustrating problems with the operation of a conventional capacitorless DRAM memory cell.

FIGS. 10A and 10B are views for illustrating problems with the operation of the conventional capacitorless DRAM memory cell.

FIGS. 11A, 11B and 11C are views for illustrating a data read operation for the conventional capacitorless DRAM memory cell.

### DETAILED DESCRIPTION OF THE PREFERRED EMBODIMENTS

Hereinafter, a method for producing a memory device using semiconductor elements (hereinafter referred to as dynamic flash memory) according to the present invention will be described with reference to the drawings.

### First Embodiment

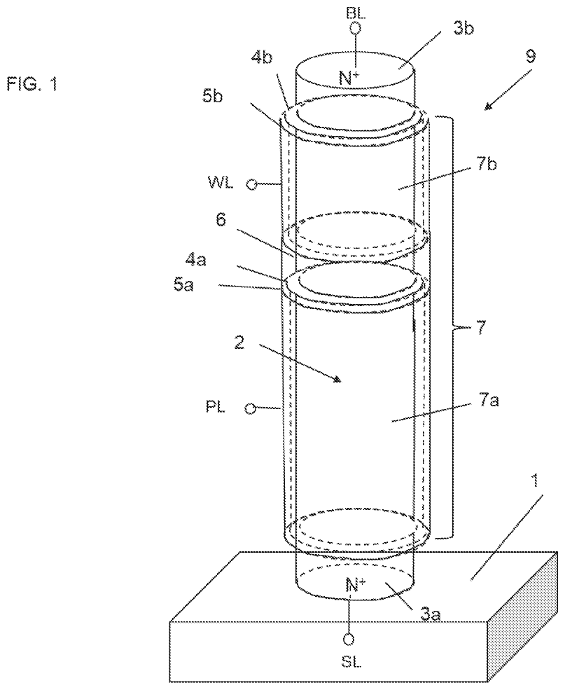

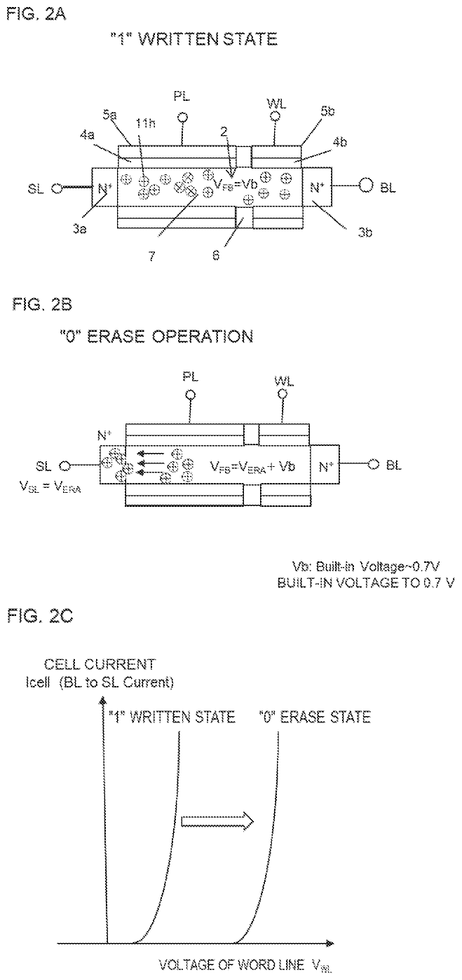

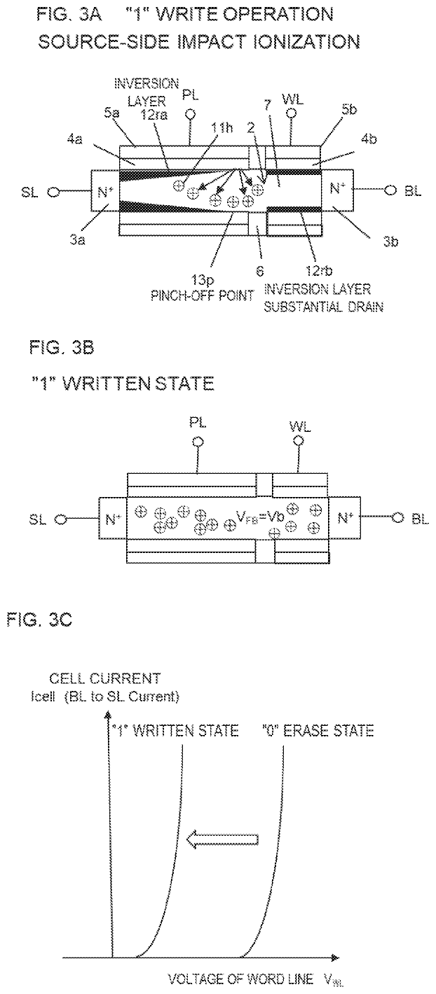

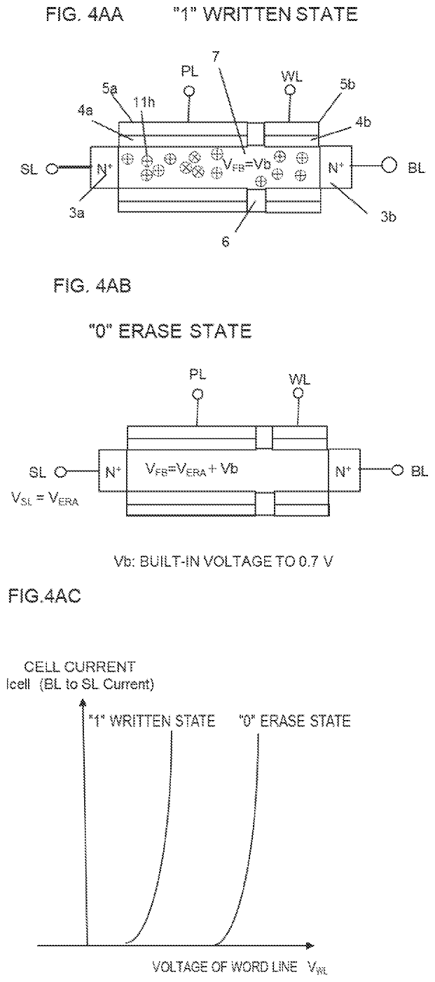

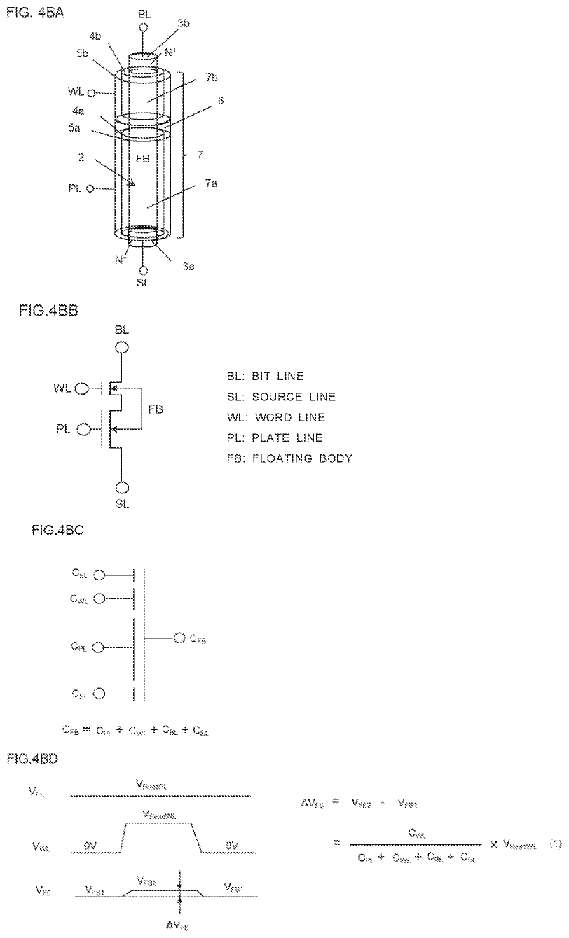

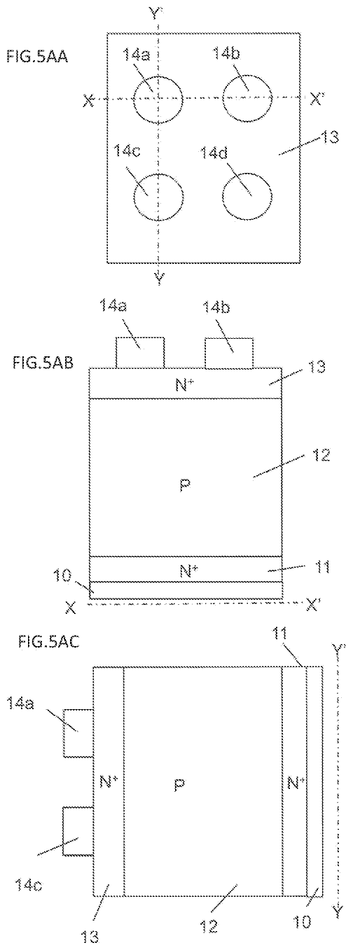

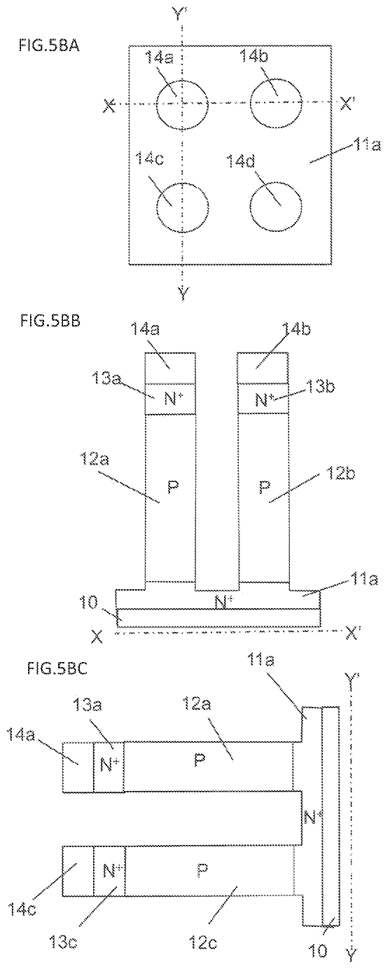

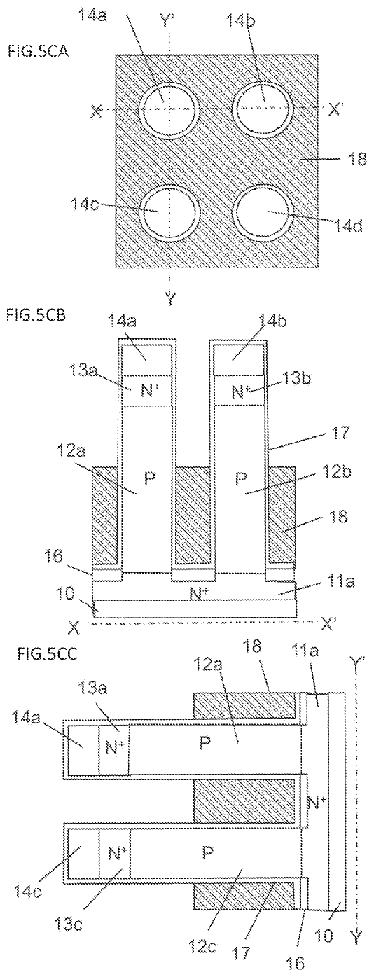

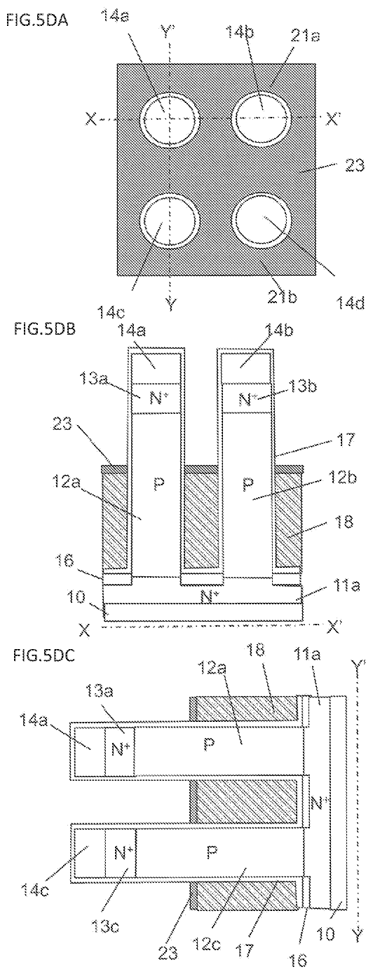

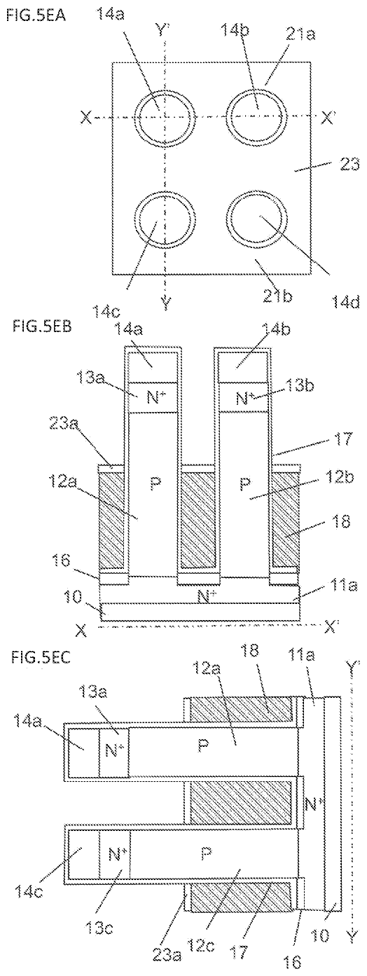

The structure, the operation mechanism, and a production method for a dynamic flash memory cell according to a first embodiment of the present invention will be described with reference to FIGS. 1 to 5K. The structure of the dynamic flash memory cell will be described with reference co FIG. 1. Then, a data erasing mechanism will be described with reference to FIGS. 2A to 2C, a data writing mechanism will be described with reference to FIGS. 3A to 3C, and a data reading mechanism will be described with reference to FIGS. 4AA to 4BC. Then, a method for producing the dynamic flash memory will be described with reference to FIGS. 5AA to 5K.

FIG. 1 illustrates the structure of the dynamic flash memory cell according to the first embodiment of the present invention. N⁺ layers 3a and 3b, one of which serves as a drain when the other serves as a source, are formed at top and bottom positions in a silicon semiconductor pillar 2 with p-type or i-type (intrinsic) conductivity (hereinafter, the silicon semiconductor pillar shall be referred to as a “Si pillar”) formed above a substrate 1. A portion of the Si pillar 2 between the N⁺ layers 3a and 3b, which serve as the source and the drain, is a channel region 7. A first gate insulating layer 4a and a second gate insulating layer 4b are formed so as to surround the channel region 7. The first gate insulating layer 4a and the second gate insulating layer 4b are respectively in contact with or located in proximity to the N⁺ layers 3a and 3b serving as the source and the drain. A first gate conductor layer 5a and a second gate conductor layer 5b are formed so as to respectively surround the first gate insulating layer 4a and the second gate insulating layer 4b. The first gate conductor layer 5a and the second gate conductor layer 5b are separated by an insulating layer 6. The channel region 7, which is the portion of the Si pillar 2 between N⁺ layers 3a and 3b, includes a first channel region 7a surrounded by the first gate insulating layer 4a and a second channel region 7b surrounded by the second gate insulating layer 4b. Accordingly, a dynamic flash memory cell 9 is formed that includes the N⁺ layers 3a and 3b serving as the source and the drain, the channel region 7, the first gate insulating layer 4a, the second gate insulating layer 4b, the first gate conductor layer 5a, and the second gate conductor layer 5b. The N⁺ layer 3a serving as the source connects to a source line SL, the N⁺ layer 3b serving as the drain connects to a bit line BL, the first gate conductor layer 5a connects to a plate line PL, and the second gate conductor layer 5b connects to a word line WL. The dynamic flash memory cell desirably has such a structure that the gate capacitance of the first gate conductor layer 5a connecting to the plate line PL is larger than the gate capacitance of the second gate conductor layer 5b connecting to the word line WL.

It should be noted that in FIG. 1, the gate length of the first gate conductor layer 5a is set longer than the gate length of the second gate conductor layer 5b so that the gate capacitance of the first gate conductor layer 5a connected to the plate line PL becomes larger than the gate capacitance of the second gate conductor layer 5b connected to the word line WL. However, it is also possible to, without setting the gate length of the first gate conductor layer 5a to be longer than the gate length of the second gate conductor layer 5b, make the thicknesses of the two gate insulating layers different such that the thickness of the gate insulating film for the first gate insulating layer 4a becomes smaller than the thickness of the gate insulating film for the second gate insulating layer 4b. Alternatively, it is also possible to make the dielectric constants of the materials of the two gate insulating layers different such that the dielectric constant of the gate insulating film for the first gate insulating layer 4a becomes higher than the dielectric constant of the gate insulating film for the second gate insulating layer 4b. As a further alternative, it is also possible to combine any of the lengths of the gate conductor lavers 5a and 5b and the thicknesses and dielectric constants of the gate insulating layers 4a and 4b so that the gate capacitance of the first gate conductor layer 5a connected to the plate line PL becomes larger than the gate capacitance of the second gate conductor layer 5b connected to the word line WL.

The data erasing mechanism will be described with reference to FIGS. 2A to 2C. The channel region 7 between the N⁺ layers 3a and 3b is electrically isolated from the substrate, and functions as a floating body. FIG. 2A illustrates a state in which holes 11 generated through impact ionization in a previous cycle are stored in the channel region 7 before the data erase operation is started. As illustrated in FIG. 2B, during the data erase operation, the voltage of the source line SL is set to a negative voltage V_{ERA}. Herein, V_{ERA} is −3 V, for example. Consequently, the P-N junction between the N⁺ layer 3a serving as the source connecting to the source line SL and the channel region 7 is forward-biased regardless of the value of the initial potential of the channel region 7. Thus, the holes 11 generated through impact ionization in the previous cycle and stored in the channel region 7 are sucked into the N⁺ layer 3a serving as the source portion, and then, the potential V_{FB} of the channel region 7 becomes V_{FB}=V_{ERA}+Vb. Herein, Vb is the built-in voltage of the P-N junction, and is about 0.7 V. Thus, when V_{ERA}=−3 V, the potential of the channel region 7 becomes −2.3 V. Such a value corresponds to the potential level of the channel region 7 in the data erase state. Therefore, when the potential of the channel region 7 functioning as the floating body becomes a negative voltage, the threshold voltage of the N-channel MOS transistor in the dynamic flash memory cell becomes high due to the substrate bias effect. Accordingly, as illustrated in FIG. 2C, the threshold voltage of the second gate conductor layer 5b connecting to the word line WL becomes high. Such a data erase state of the channel region 7 corresponds to logical memory data “0.” It should be noted that the aforementioned conditions of the voltages applied to the bit line BL, the source line SL, the word line WL, and the plate line PL are only examples for performing a data erase operation. Thus, other operating conditions may also be employed as long as a data erase operation can be performed.

FIGS. 3A to 3C illustrate a data write operation for the dynamic flash memory cell according to the first embodiment of the present invention. As illustrated in FIG. 3A, 0 V for example, is input to the N⁺ layer 3a connecting to the source line SL, 3 V, for example, is input to the N⁺ layer 3b connecting to the bit line BL, 2 V, for example, is input to the first gate conductor layer 5a connecting to the plate line PL, and 5 V, for example, is input to the second gate conductor layer 5b connecting to the word line WL. Consequently, as illustrated in FIG. 3A, an inversion layer 12ra is formed on the inner periphery of the channel region 7 on the inner side of the first gate conductor layer 5a connecting to the plate line PL, and a first N-channel MOS transistor region including the channel region 7a surrounded by the first gate conductor layer 5a is operated in the saturation region. Thus, the inversion layer 12ra on the inner side of the first gate conductor layer 5a connecting to the plate line PL has a pinch-off point 13. Meanwhile, a second N-channel MOS transistor region including the channel region 7b surrounded by the second gate conductor layer 5b connecting to the word line WL is operated in the linear region. Thus, there is no pinch-off point on the inner side of the second gate conductor layer 5b connecting to the word line WL, and an inversion layer 12rb is formed on the entire surface. The inversion layer 12rb formed on the entire surface on the inner side of the second gate conductor layer 5b connecting to the word line WL functions as a substantial drain of the second N-channel MOS transistor region including the second gate conductor layer 5b. Thus, an electric field in a first boundary region of the channel region 7 between the first N-channel MOS transistor region and the second N-channel MOS transistor region, which are connected in series, becomes maximum, and an impact ionization phenomenon occurs in the region. Such a region is a region on the source side as seen from the second N-channel MOS transistor region connecting to the word line WL. Thus, such a phenomenon is called a source-side impact ionization phenomenon. Due to the source-side impact ionization phenomenon, electrons flow from the N⁺ layer 3a connecting to the source line SL to the N⁺ layer 3b connecting to the bit line BL. The accelerated electrons collide with Si lattice atoms, and electron-hole pairs are generated due to the kinetic energy. Some of the generated electrons flow into the first gate conductor layer 5a and the second gate conductor layer 5b, but most of them flow into the N⁺ layer 3b connecting to the bit line BL. To write “1,” it is also possible to generate electron-hole pairs using a GIDL (Gate Induced Drain Leakage) current (see E. Yoshida, and T. Tanaka: “A Capacitorless 1T-DRAM Technology Using Gate-Induced Drain-Leakage (GIDL) Current for Low-Power and High-Speed Embedded Memory,” IEEE Transactions on Electron Devices, Vol. 53, No. 4, pp. 692-697, Apr. 2006), and then fill the floating body FB with the generated holes.

As illustrated in FIG. 3B, the generated holes 11 are the majority carriers in the channel region 7, and charge the channel region 7 in a positively biased manner. Since the N⁺ layer 3a connecting to the source line SL is at 0 V, the channel region 7 is charged up to the built-in voltage Vb (about 0.7 V) of the P-N junction between the N⁺ layer 3a connecting to the source line SL and the channel region 7. When the channel region 7 is charged in a positively biased manner, the threshold voltage of each of the first N-channel MOS transistor region and the second N-channel MOS transistor region becomes low due to the substrate bias effect. Accordingly, as illustrated in FIG. 3C, the threshold voltage of the N-channel MOS transistor in the second channel region 7b connecting to the word line WL becomes low. Such a written state of the channel region 7 is allocated as logical memory data “1.”

It should be noted that during the write operation, it is also possible to generate electron-hole pairs through an impact ionization phenomenon or using a GIDL current not in the aforementioned first boundary region but in a second boundary region between the first impurity layer and the first channel semiconductor layer or a third boundary region between the second impurity layer and the second channel semiconductor layer, and then charge the channel region 7 with the generated holes 11. It should be also noted that the aforementioned conditions of the voltages applied to the bit line BL, the source line SL, the word line WL, and the plate line PL are only examples for performing a write operation. Thus, other operating conditions may also be employed as long as a write operation can be performed.

A data read operation for the dynamic flash memory cell according to the first embodiment of the present invention and the memory cell structure related thereto will be described with reference to FIGS. 4AA to 4BD. A read operation for the dynamic flash memory cell will be described with reference to FIGS. 4AA to 4AC. As illustrated in FIG. 4AA, when the channel region 7 is charged up to the built-in voltage Vb (about 0.7 V), the threshold voltage of the N-channel MOS transistor drops due to the substrate bias effect. Such a state allocated as the logical memory data “1.” As illustrated in FIG. 4AB, in a memory block selected before a write operation is performed, the channel region 7, which has been set to the erase state “0” in advance, has a floating voltage V_{FB} of V_{ERA}+Vb. Through a write operation, the written state “1” is randomly stored. Consequently, logical memory data at logic levels “0” and “1” are created for the word line WL. As illustrated in FIG. 4AC, data reading is performed with a sense amplifier by utilizing the difference in level between the two threshold voltages for the word line WL. It should be noted that in reading data, setting the voltage applied to the first gate conductor layer 5a connecting to the plate line PL to be higher than the threshold voltage corresponding to the logical memory data “1” and lower than the threshold voltage corresponding to the logical memory data “0” can obtain such characteristics that no current flows even when the voltage of the word line WL is set high for reading the logical memory data “0” as illustrated in FIG. 4AC.

The magnitude relationship between the gate capacitances of the first gate conductor layer 5a and the second gate conductor layer 5b during a data read operation for the dynamic flash memory cell according to the first embodiment of the present invention, and an operation related thereto will be described with reference to FIGS. 4BA to 4BD. It is desirable that the gate capacitance of the second gate conductor layer 5b connecting to the word line will be designed to be smaller than the gate capacitance of the first gate conductor layer 5a connecting to the plate line PL. As illustrated in FIG. 4BA, the length in the vertical direction of the first gate conductor layer 5a connecting to the plate line PL is set longer than the length in the vertical direction of the second gate conductor layer 5b connecting to the word line WL so that the gate capacitance of the second gate conductor layer 5b connecting to the word line WL becomes smaller than the gate capacitance of the first gate conductor layer 5a connecting to the plate line PL. FIG. 4BB illustrates an equivalent circuit of a single cell of the dynamic flash memory in FIG. 4BA. In addition, FIG. 4BC illustrates the relationship among the coupled capacitances of the dynamic flash memory. Herein, C_{WL} represents the capacitance of the second gate conductor layer 5b, C_{PL} represents the capacitance of the first gate conductor layer 5a, C_{BL} represents the capacitance of the P-N junction between the N⁺ layer 3b serving as the drain and the second channel region 7b, and C_{SL} represents the capacitance of the P-N junction between the N⁺ layer 3a serving as the source and the first channel region 7a. As illustrated in FIG. 4BD, when the voltage of the word line WL oscillates, the operation has influence as noise on the channel region 7. Potential fluctuation ΔV_{FB} of the channel region 7 at this time is represented as follows.

ΔV_{FB}=C_{WL}=/(C_{PL}+C_{WL}+C_{BL}+C_{SL})×V_{ReadWL} (1)

Herein, V_{ReadWL} is the oscillating potential of the word line WL during reading. As is obvious from above, ΔV_{FB} can be made small by setting the contribution rate of C_{WL} low in comparison with the entire capacitance C_{PL}+C_{WL}+C_{BL}+C_{SL} of the channel region 7. C_{BL}+C_{SL} is the capacitance of the P-N junctions. To increase such capacitance, for example, the diameter of the Si pillar 2 is increased, which is, however, undesirable for downsizing the memory cell. In contrast, it is also possible to further reduce ΔV_{FB} by setting the length in the vertical direction of the first gate conductor layer 5a connecting to the plate line PL to be further longer than the length in the vertical direction of the second gate conductor layer 5b connecting to the word line WL, without decreasing the degree of integration of the memory cell as seen in plan view. It should be noted that in reading data, setting the voltage applied to the first gate conductor layer 5a connecting to the plate line PL to be higher than the threshold voltage corresponding to the logical memory data “1” and lower than the threshold voltage corresponding to the logical memory data “0” can obtain such characteristics that no current flows even when the voltage of the word line WL is set high for reading the logical memory data “0.” The aforementioned conditions of the voltages applied to the bit line BL, the source line SL, the word line WL, and the plate line PL are only examples for performing a data read operation. Thus, other operating conditions may also be employed as long as a data read operation can be performed. Such a data read operation may also be performed through a bipolar operation.

A method for producing the dynamic flash memory of the present embodiment will be illustrated with reference to FIGS. 5AA to 5JC. Among the drawings, FIGS. 5AA, 5BA, 5DA, 5EA, 5FA, 5GA, 5HA, 5IA and 5JA illustrate plan views, FIGS. 5AB, 5BB, 5CB, 5DB, 5EB, 5FB, 5GB, 5HB, 5IB and 5JB illustrate cross-sectional views along line X-X′ in FIGS. 5AA to 5JA, and FIGS. 5AC, 5BC, 5CC, 5CC, 5EC, 5FC, 5GC, 5HC, 5IC and 5JC illustrate cross-sectional views along line Y-Y′ in FIGS. 5AA to 5JA. In addition, FIG. 5K illustrates a schematic structural view of FIGS. 5J.

As illustrated in FIGS. 5AA to 5AC, an N⁺ layer 11 (which is an example of a “first impurity region” in the claims), a P layer 12 of Si, and an N⁺ layer 13 are formed in this order from the lower side on a substrate 10 (which is an example of a “substrate” in the claims). In addition, mask material layers 14a, 14b, 14c, and 14d, which are circular in shape as seen in plan view, are formed. It should be noted that the substrate 10 may be formed using SOI (Silicon On Insulator), or one or more layers of Si or other semiconductor materials. Alternatively, the substrate 10 may be a well layer including a single N⁺ layer, a single P layer, multiple N layers, or multiple P layers.

Next, as illustrated in FIGS. 5BA to 5BC, the N⁺ layer 13, the P layer 12, and the upper portion of the N⁺ layer 11 are etched using the mask material layers 14a to 14d as masks so that Si pillars 12a (which is an example of a “first semiconductor pillar” in The claims), 12b, 12c, and 12d (not illustrated) and N⁺ layers 13a, 13b, 13c, and 13d (not illustrated; each of which is an example of a “second impurity region” in the claims) are formed on the N⁺ layer 11a.

Next, as illustrated in FIGS. 5CA to 5CC, a HfO₂ layer 17 as a gate insulating layer is formed covering the entire surface, using ALD (Atomic Layer Deposition), for example. Then, a TiN layer (not illustrated) to serve as a gate conductor layer is formed covering the entire surface. Then, the TiN layer is polished through CMP (Chemical Mechanical Polishing) so that its upper surface position is located at the level of the upper surfaces of the mask material lavers 14a to 14d. Then, the TiN layer is etched through RIE (Reactive Ion Etching) so that its upper surface position in the vertical direction is located around the intermediate positions of the Si pillars 12a to 12d, whereby a TiN layer 18 (which is an example of a “first gate conductor layer” in the claims) is formed. It should be noted that the HfO₂ layer 17 may have a two-layer structure of a SiO₂ layer, which is formed first through low-temperature oxidation or ALD (Atomic Layer Deposition), and a HfO₂ film. Alternatively, the HfO₂ layer 17 may be other single-layer or multilayer insulating layers as long as such insulating layers function as a gate insulating layer. In addition, as the TiN layer 18, other single-layer or multilayer conductor layers may be used as long as such conductor layers have the function of a gate conductor layer. The TiN layer is desirably etched so that its upper surface position in the vertical direction is located above the intermediate positions of the Si pillars 12a to 12d. It should be noted that the TiN layer 18 outside of the memory cell region is removed.

Next, as illustrated in FIGS. 5DA to 5DC, a SiGe layer 23 (which is an example of a “first material layer” in the claims), for example, is formed on the TiN layer 18 using the selective epitaxial growth method. In such a case, the SiGe layer 23 is grown only on the TiN layer 18 and is not formed on the HfO₂ layer 17 surrounding the exposed Si pillars 12a to 12d.

Next, as illustrated in FIGS. 5EA to 5EC, the SiGe layer 23 is oxidized to form a SiO₂ layer 23a (which is an example of a “first oxidized insulating layer” in the claims).

Next, as illustrated in FIGS. 5FA to 5FC, a portion of the HfO₂ layer 17 at a level above the SiO₂ layer 23a is etched to form a HfO₂ layer 17a (which is an example of a “first gate insulating layer” in the claims). Then, a HfO₂ layer 17b (which is an example of a “second gate insulating layer” in the claims) is formed on the entire surface. Then, a TiN layer (not illustrated) is formed covering the entire surface using the CVD method. Then, the TiN layer is polished using the CMP method and is then etched using the RIE method so that its upper surface position is located around the lower ends of the N⁺ layers 13a to 13d, whereby a TiN layer 26 is formed. Then, a SiGe layer 25 is formed on the TiN layer 26 using the selective growth method. Then, the SiGe layer 25 is oxidized to form SiO₂ layers 25a and 25b.

Next, as illustrated in FIGS. 5GA to 5GC, the SiGe layer 25 is oxidized to form a SiO₂ layer 25a. Then, a SiN layer 27a, which surrounds the side faces of the N⁺ layers 13a and 13b and the mask material layers 14a and 14b and is continuous, is formed. Similarly, a SiN layer 27b, which surrounds the side faces of the N⁺ layers 13c and 13d and the mask material layers 14c and 14d and is continuous, is formed. Then, the SiO₂ layer 25a and the TiN layer 26 are etched using the SiN layers 27a and 27b as masks so that TiN layers 26a (which is an example of a “second gate conductor layer” in the claims) and 26b are formed. Herein, the distance L1 between two intersections between line X-X′ and the outer circumferential lines of the HfO₂ layer 17b surrounding the Si pillars 12a and 12b is set shorter than twice the width L2 of each of the SiN layers 27a and 27b in the Y-Y′ direction, and the distance L3 between two intersections between line Y-Y′ and the outer circumferential lines of the HfO₂ layer 17b surrounding the Si pillars 12a and 12c is set longer than twice the width L2. Accordingly, the SiN layer 27a can be formed such that it is continuous around the Si pillars 12a and 12b and is separated between the Si pillars 12a and 12c. Similarly, the SiN layer 27b is formed such that it is continuous around the Si pillars 12c and 12d and is separated between the Si pillars 12a and 12c. It should be noted that the HfO₂ layer 17b may have a two-layer structure of a SiO₂ layer, which is formed first through low-temperature oxidation or ALD (Atomic Layer Deposition), and a HfO₂ film. Alternatively, the HfO₂ layer 17b may be other single-layer or multilayer insulating layers as long as such insulating layers function as a gate insulating layer. In addition, as the TiN layer 18, other single-layer or multilayer conductor layers may be used as long as such conductor layers have the function of a gate conductor layer.

Next, as illustrated in FIGS. 5HA to 5HD, a SiO₂ layer 29 is formed that includes voids 31aa, 31ab, 31ac, 31ba, 31bb, 31bc, 31ca, 31cb, and 31cc between the side faces of and around the TiN layers 26a and 26b and the SiN layers 27a and 27b. FIG. 5HD is a cross-sectional view along line X1-X1′ in FIG. 5HA (this is also true of FTGS. 5I). It should be noted that the voids 31aa, 31ab, 31ac, 31ba, 31bb, 31bc, 31ca, 31cb, and 31cc are formed such that their upper end positions are located at a level lower than the upper end positions of the TiN layers 26a and 26b indicated by the dotted line in FIG. 5HD.

Next, as illustrated in FIGS. 5IA to 5ID, the mask material layers 14a to 14d are etched to form contact holes 30a, 30b, 30c, and 30d.

Next, as illustrated in FIGS. 5JA to 5JD, a bit line conductor layer BL1 (32a) is formed that connects to the N⁺ layers 13a and 13c via the contact holes 30a and 30c, respectively, and also, a bit line conductor layer BL2 (32b) is formed that connects to the N⁺ layers 13b and 13d via the contact holes 30b and 30d, respectively. Then, a SiO₂ layer 33 is formed that includes voids 34a, 34b, and 34c between and on the opposite sides of the bit line conductor layer BL1 (32a) and the bit line conductor layer BL2 (32b). Accordingly, dynamic flash memory is formed on the substrate 10. The TiN layers 26a and 26b respectively serve as word line conductor layers WL1 and WL2. The TiN layer 18 serves as a plate line conductor layer PL that also serves as a gate conductor layer. The N⁺ layer 11a serves as a source line conductor layer SL that also serves as a source impurity layer.

FIG. 5K illustrates a schematic structural views of the dynamic flash memory illustrated in FIGS. 5JA to 5JC. The N⁺ layer 11a as the source line conductor layer SL is formed continuous over the entire surface. The PL line conductor layer PL is also formed continuous over the entire surface. The gate conductor TiN layer 26a connecting to the word line conductor layer WL1 is formed continuous around the adjacent Si pillars 12a and 12b in the X-direction. Likewise, the gate conductor TiN layer 26b connecting to the word line conductor layer WL2 is formed continuous around the adjacent Si pillars 12c and 12d in the X-direction. In addition, the bit line conductor layer BL1 connecting to the N⁺ layers 13a and 13c, and the bit line conductor layer BL2 connecting to the N⁺ layers 13b and 13d are formed in the Y-direction orthogonal to the X-direction.

In FIGS. 5DA to 5DC and 5EA to 5EC, the SiGe layer 23 is formed on the TiN layer 18 using the selective growth method, for example, and then, the SiGe layer 23 is oxidized to form the SiO₂ layer 23a. In contrast, the SiGe layer 23 may be other metal or semiconductor material layers as long as such materials can be grown only on the TiN layer 18 and are not formed on the HfO₂ layer surrounding the exposed Si pillars 12a to 12d, and then can be oxidized to form an oxide layer. In addition, the HfO₂ layer 17 may be other material layers as long as such materials allow the SiGe layer 23 to be selectively formed on the TiN layer 18. Further, the TiN layer 18 may be other conductive material layers as long as such materials allow a material layer corresponding to the SiGe layer 23 to be selectively deposited thereon and have the function of a gate conductor layer. This is also true of the formation of the TiN layer 26, the SiGe layer 25, and the SiO₂ layers 25a and 25b described with reference to FIGS. 5FA to 5FC and 5GA to 5GC.

In the foregoing description, the SiGe layers 23 and 25 are entirely oxidized to form the SiO₂ layers 23a, 25a, and 25b, but it is also possible to oxidize only the surface layers of the SiGe layers 23 and 25 to form the SiO₂ layers 23a, 25a, and 25b. In addition, it is also possible to use a thin TiN layer instead of the TiN layer 18, and deposit thick low-resistance doped poly-Si instead of the SiGe layer 23. In such a case, oxidizing the surface layer of the thick low-resistance doped poly-Si can form the SiO₂ layer 23a. Alternatively, the TiN layer 18 and the SiGe layer 23 may be formed using a single low-resistance doped poly-Si layer. Instead of such a doped poly-Si layer, it is also possible to use other low-resistance conductor layers that can be oxidized to form an oxide film.

It should be noted that in FIG. 1, the length in the vertical direction of the first gate conductor layer connecting to the plate line PL is set further longer than the length in the vertical direction of the second gate conductor layer 5b connecting to the word line WL to that C_{PL}≥C_{WL}. However, it is possible to reduce the capacitive coupling ratio (C_{WL}/(C_{PL}+C_{WL}+C_{BL}+C_{SL})) of the word line WL to the channel region 7 only by adding the plate line PL. Consequently, potential fluctuation ΔV_{FB} of the channel region 7 as the floating body becomes small.

In addition, a fixed voltage may be applied as the voltage V_{ErasePL} of the plate line PL regardless of each operation mode. In addition, 0 V, for example, may be applied as the voltage V_{ErasePL} of the plate line PL only during erasing. Further, a fixed voltage or a voltage that changes with time may be applied as the voltage V_{ErasePL} of the plate line PL as long as such a voltage satisfies the condition that the dynamic flash memory operation can be performed.

The dynamic flash memory operation described in the present embodiment can be performed regardless of whether the horizontal cross-sectional shape of the Si pillar 2 in FIG. 1 is circular, elliptical, or rectangular. Further, it is also possible to form dynamic flash memory cells with different shapes, such as circular, elliptical, and rectangular, in a mixed manner on a single chip. This is also true of FIGS. 5AA to 5K.

In FIG. 1, in the vertical direction, in a portion of the channel region 7 surrounded by the insulating layer 6, potential distributions of the first channel region 7a and the second channel region 7b are formed continuously. Accordingly, the channel region 7 including The first channel region 7a and the second channel region 7b is continuous in the vertical direction across its region surrounded by the insulating layer 6.

In the step described with reference to FIGS. 5GA to 5GC, it is also possible to etch the TiN layers 26a and 26b, the HfO₂ layer 17b, and the TiN layer 18 using the SiN layers 27a and 27b as masks so as to form TiN layers resulting from the TiN layer 18 separated in the same shape as the TiN layers 26a and 26b as seen in plan view. In such a case, the TiN layers separated between the Si pillars 12a and 12b and the Si pillars 12c and 12d and surrounding the respective Si pillars 12 are formed. Such separated TiN layers are connected individually or commonly to the driving plate line. Alternatively, such separated TiN layers may be connected to the word lines WL, while the TiN layers 26a and 26b may be connected to the plate line PL.

FIGS. 5AA to 5JC illustrate the method for producing the dynamic flash memory cell including two gate conductor layers, which include the TiN layer 18 and the TiN layers 26a and 26b, in the vertical direction. In contrast, it is also possible to add a step of, after forming the TiN layers 26a and 26b and the SiO₂ layers 25a and 25b, forming third gate conductor layers surrounding the Si pillars 12a to 12d and the gate insulating layers. In such a case, the lengths of the Si pillars 12a to 12d in the vertical direction are set greater than or equal to at least the lengths of the third gate conductor layers. In such a case, the first-stage gate conductor layer (i.e., the TiN layer 18) and the third-stage gate conductor layers are formed such that their shapes as seen in plan view are the same as the shapes of the second-stage gate conductor layers (i.e., the TiN layers 26a and 26b). Each of the three gate conductor layers is connected to the word line WL or the plate line PL. The second-stage gate conductor layers may be connected to the plate line PL, while the first-stage and third-stage gate conductor layers may be connected to the word lines WL.

The present embodiment has the following features.

### Feature 1

In the dynamic flash memory cell of the present embodiment, the N⁺ layers 3a and 3b serving as the source and the drain, the channel region 7, the first gate insulating layer 4a, the second gate insulating layer 4b, the first gate conductor layer 5a, and the second gate conductor layer 5b are formed in a pillar shape as a whole. The N⁺ layer 3a serving as the source connects to the source line SL, the N⁺ layer 3b serving as the drain connects to the bit line BL, the first gate conductor layer 5a connects to the plate line PL, and the second gate conductor layer 5b connects to the word line WL. The dynamic flash memory cell has such a structure that the gate capacitance of the first gate conductor layer 5a connecting to the plate line PL is larger than the gate capacitance of the second gate conductor layer 5b connecting to the word line WL. In the present dynamic flash memory cell, the first gate conductor layer 5a and the second gate conductor layer 5b are stacked in the vertical direction. Therefore, even when the dynamic flash memory cell has such a structure that the gate capacitance of the first gate conductor layer 5a connecting to the plate line PL is larger than the gate capacitance of the second gate conductor layer 5b connecting to the word line WL, the memory cell area as seen in plan view is not increased. This can achieve higher performance and a higher degree of integration of the dynamic flash memory cell at the same time.

### Feature 2

The voltage of the word line WL oscillates up and down while a write operation or a read operation is performed on the dynamic flash memory cell. At this time, the plate line PL performs the role of reducing the capacitive coupling ratio between the word line WL and the channel region 7. Consequently, it is possible to significantly suppress the influence of changes in the voltage of the channel region 7 when the voltage of the word line WL oscillates up and down. Accordingly, it is possible to increase the difference between the threshold voltages of the SGT transistor connecting to the word line WL corresponding to logic levels of “0” and “1.” This leads to an increased operation margin of the dynamic flash memory cell.

### Feature 3

In FIGS. 5DA to 5DC and 5EA to 5FC, the SiGe layer 23 is formed on the TiN layer 18 using the selective growth method, for example, and then, the SiGe layer 23 is oxidized to form the SiO₂ layer 23a. The SiO₂ layer 23ais an insulating layer for electrically isolating the gate TiN layer 18 connecting to the plate line PL and the gate TiN layers 26a and 26b connecting to the word lines WL. Alternatively, when doped poly-Si is deposited instead of the SiGe layer 23, the upper surface of the doped poly-Si is oxidized to form an insulating layer for electrical isolation. The conventional method for forming the SiO₂ layer 23a involves the deposition of a SiO₂ layer using the CVD method, polishing through CMP, and RIP etching. In such a method, a SiO₂ film is deposited first on the entire surface using the CVD method. Then, the SiO₂ film is polished using the CMP method so that its upper surface position is located at the level of the upper surface positions of the mask material layers 14a to 14d. Then, the SiO₂ film is etched using the RIE method so that the SiO₂ film with a predetermined thickness remains on the TiN layer 18. If the etching proceeds excessively and the SiO₂ film is entirely removed beyond the upper surface of the TiN layer 18, an electrical short circuit occurs between the TiN layer 18 and the TiN layers 26a and 26b. Thus, the RIE method requires high controllability and high uniformity across the entire wafer surface. In contract, the production method of the present invention does not use the RIE method that requires high controllability. Accordingly, there is no possibility of an electrical short circuit between the TiN layer 18 and the TiN layers 26a and 26b, which would otherwise occur due to over-etching using the RIE method if the conventional method is used.

### Feature 4

In FIGS. 5EA to 5EC, the SiGe layer 23 is entirely oxidized to form the SiO₂ layer 23a. However, even when the SiGe layer 23 is not entirely oxidized, the TiN layer 18 and the TiN layers 26a and 26b are insulated. Accordingly, insulation between the TiN layer 18 and the TiN layers 26a and 26b can be easily achieved. Further, even when a conductor layer, which contains doped poly-Si in its upper layer or its entirety, is formed instead of the TiN layer 18, and the surface layer thereof is oxidized, insulation is similarly achieved.

### Feature 5

The oxidation rate of the SiGe layer 23 is higher than that of Si (for example, see A. Veloso, et. al.: “Vertical Nanowire and Nanosheet FETs: Device Features, Novel Schemes for improved Process Control and Enhanced Mobility, Potential for Faster & More Energy Efficient Circuits” IEDM19 Digest Papers, pp.230-233, 2019). Accordingly, even without entirely oxidizing the SiGe layer 23 in FIGS. 5EA to 5EC, for example, it is possible to form the SiO₂ layer 23a by, before forming the HfO₂ layer 17b in FIGS. 5A to 5FC, forming a thin SiO₂ layer on each of the side faces of the Si pillars 12a to 12d and promoting the oxidation of the SiGe layer 23 at the same time. This is also true of doped poly-Si containing a large amount of impurities. This simplifies the process design for forming the SiO₂ layer 23a for insulating the TiN layer 18 and the TiN layers 26a and 26b.

### Feature 6

As illustrated in FIGS. 5FA to 5FC and 5GA to 5GC, the SiO₂ layer 25a formed by oxidizing the SiGe layer 25, which has been selectively grown on the TiN layer 26, serves as an etching stopper layer for protecting the TiN layer 26 in forming the SiN layers 27a and 27b. This facilitates the formation of the TiN layers 26a and 26b connecting to the word lines WL. In addition, when the contact holes 30a to 30d are formed wider to surround the respective side faces of the N⁺ layers 13a to 13d so as to decrease the connection resistance between the N⁺ layers 13a to 13d and the bit line conductor layers BL1 (32a) and BL2 (32b), the SiO₂ layer 25a serves as an etching stopper layer in forming the contact holes 30a to 30d and also serves as an insulating layer for electrically isolating the TiN lavers 26a and 26b and the bit line conductor layers BL1 (32a) and BL2 (32b).

### Second Embodiment

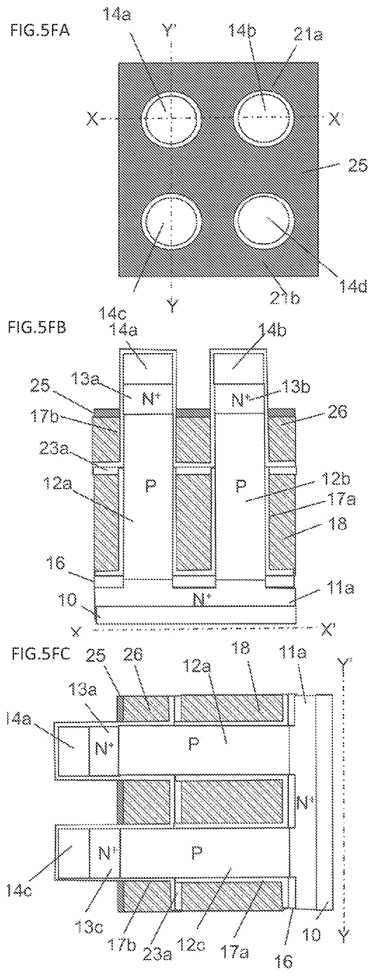

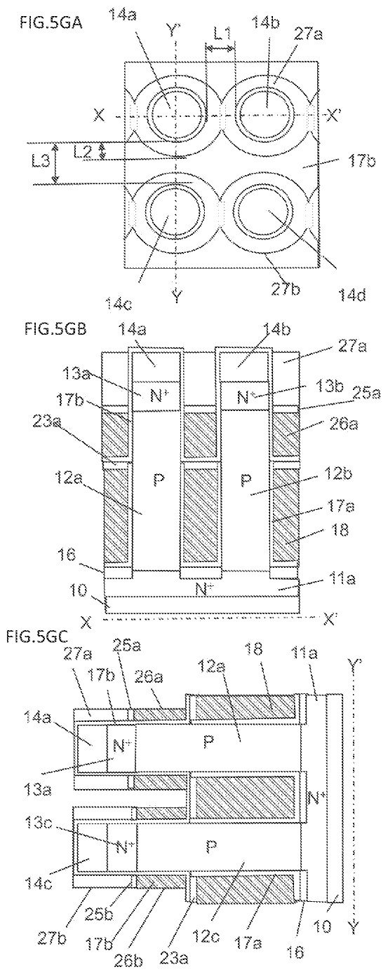

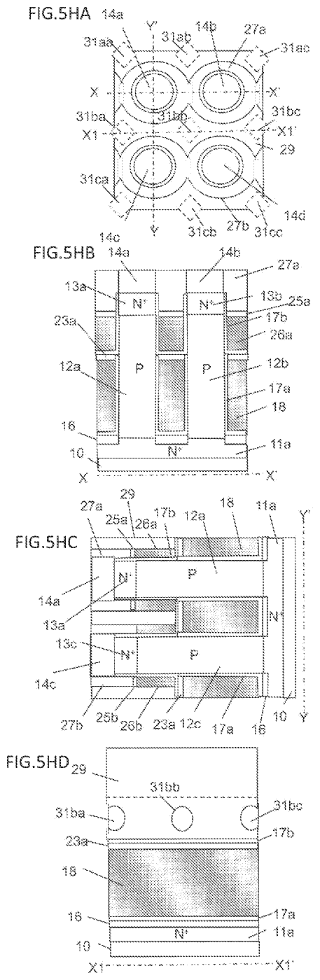

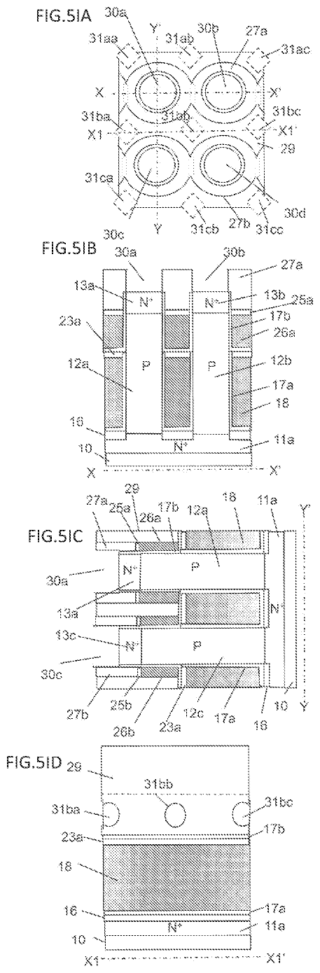

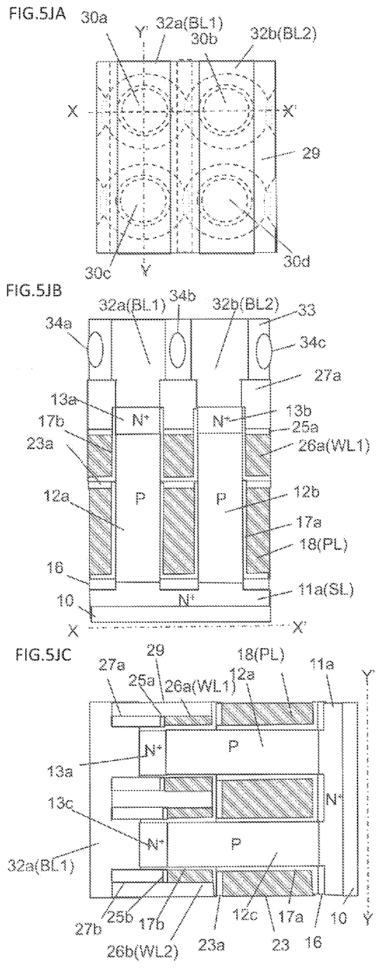

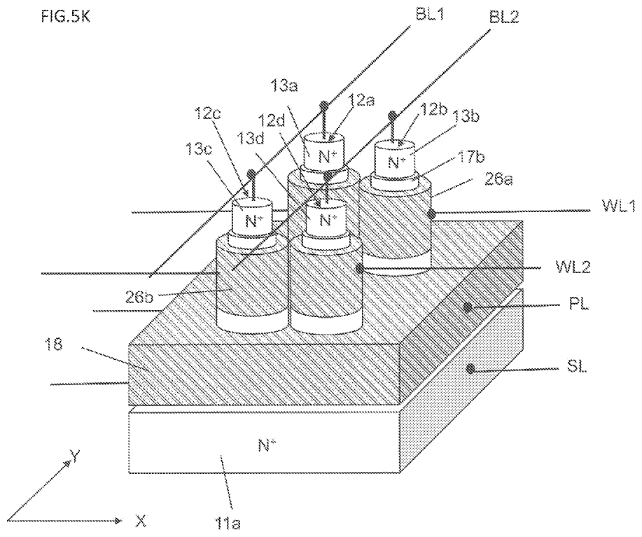

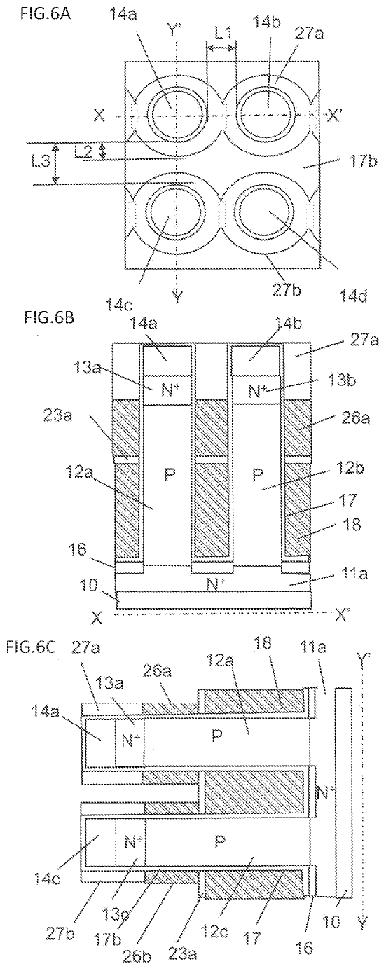

A method for producing dynamic flash memory of a second embodiment will be described with reference to FIGS. 6A to 6C. Among FIGS. 6A to 6C, FIG. 6A is a plan view, FIG. 6B is a cross-sectional view along line X-X′ in FIG. 6A, and FIG. 6C is a cross-sectional view along line Y-Y′ in FIG. 6A.

The steps illustrated in FIGS. 5AA to 5EC are performed. Then, as illustrated in FIGS. 6A to 6C, a portion of the HfO₂ layer 17 at a level above the SiO₂ layer 23a in the vertical direction is left, and then, SiN layers 27a and 27b and TiN layers 26a and 26b are formed on the outer periphery of the HfO₂ layer 17 as in the step illustrated in FIGS. 5GA to 5GC. Then, the steps illustrated in FIGS. 5HA to 5JC are performed to form dynamic flash memory on the substrate 10.

The present embodiment has the following features.

In the present embodiment, the first gate insulating layer and the second gate insulating layer are formed using a single HfO₂ layer 17. Accordingly, there is no need to separately form the HfO₂ layer 17b, which is the second gate insulating layer connecting to the word line WL, and the HfO₂ layer 17a, which is the first gate insulating layer connecting to the lower plate line PL, unlike in the first embodiment. This can simplify the production steps.

### Third Embodiment

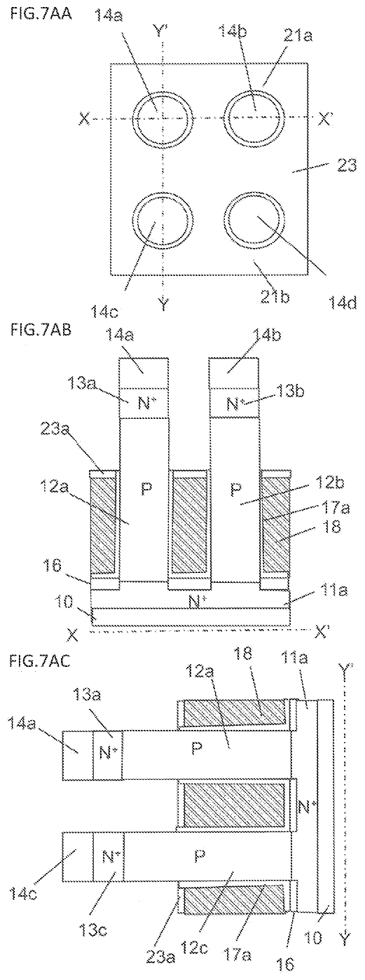

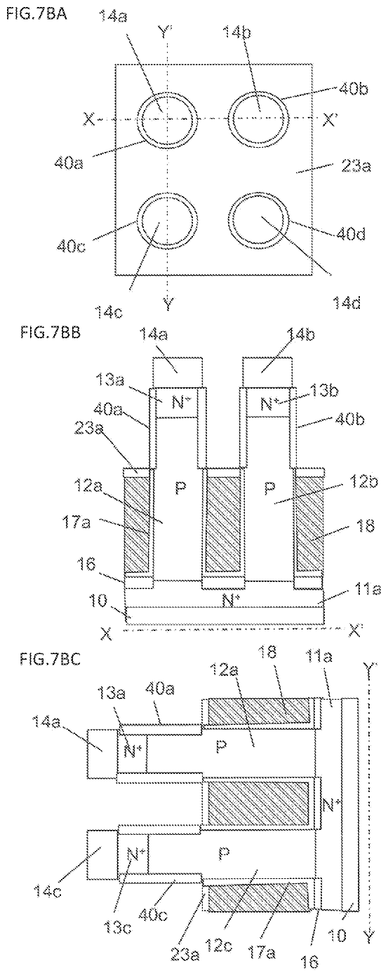

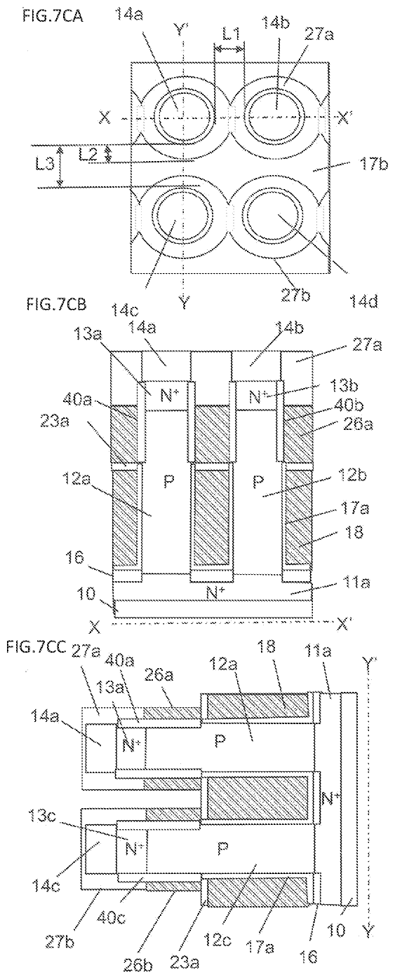

A method for producing dynamic flash memory of a third embodiment will be described with reference to FIGS. 7AA to 7CC. Among the drawings, FIGS. 7AA, 7BA and 7CA are plan views, FIGS. 7AB, 7BB and 7CB are cross-sectional views along line X-X′ in FIGS. 7AA, 7BA and 7CA, and FIGS. 7AC, 7BC and 7CC are cross-sectional views along line Y-Y′ in FIGS. 7AA, 7BA and 7CA.

The steps illustrated in FIGS. 5AA to 5EC are performed. Then, as illustrated in FIGS. 7AA to 7AC, a portion of the HfO₂ layer 17 at a level above the SiO₂ layer 23a in the vertical direction is etched to form a HfO₂ layer 17a.

Next, as illustrated in FIGS. 7BA to 7BC, the exposed side faces of the Si pillars 12a to 12d are oxidized at a low temperature to form SiO₂ layers 40a, 40b, 40c, and 40d. Then, the steps illustrated in FIGS. 5FA to 5FC are performed.

Next, as illustrated in FIGS. 7CA to 7CC, a TiN layer 26a, which surrounds the side faces of the SiO₂ layers 40a and 40b and the mask material layers 14a and 14b and is continuous, and a TiN layer 26b, which surrounds the side faces of the SiO₂ layers 40c and 40d and the mask material layers 14c and 14d and is continuous, are formed. Then, the steps illustrated in

FIGS. 5HA to 5JC are performed to form dynamic flash memory on the substrate 10.

The present embodiment has the following features.

In the present embodiment, each of the SiO₂ layers 40a to 40d is formed as the second gate insulating layer. In contrast, the HfO₂ layer 17a of a material with a high dielectric constant is used as the first gate insulating layer. Thus, it is possible to easily set the gate capacitance of the SGT connecting to the plate line larger than the gate capacitance of the SGT connecting to the word line WL. This allows for a more stable operation of the dynamic flash memory.

### Fourth Embodiment

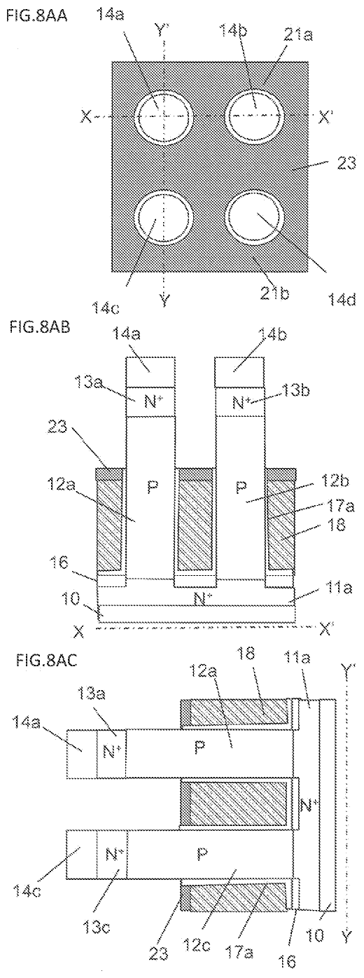

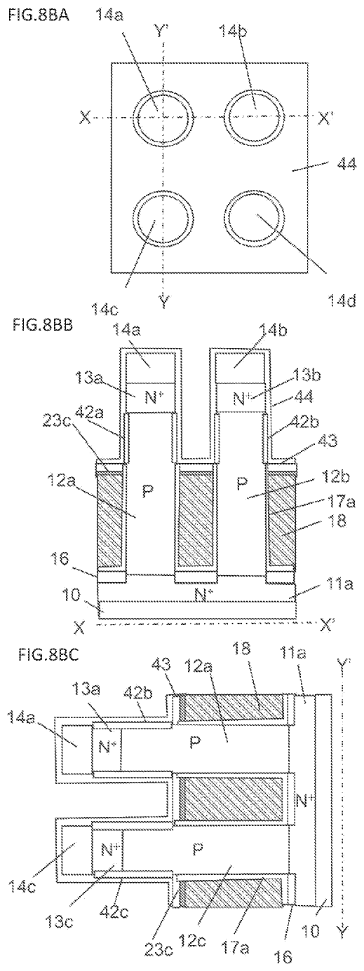

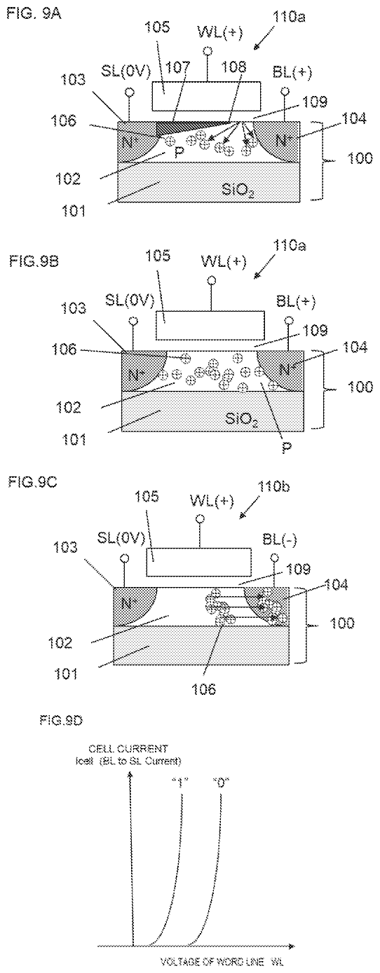

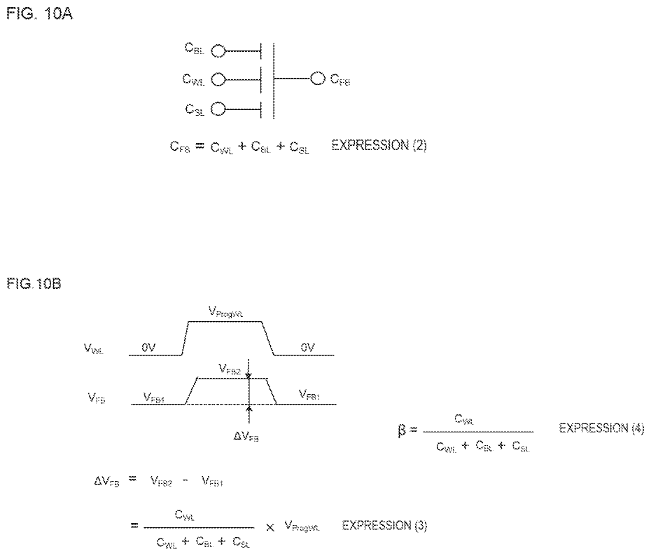

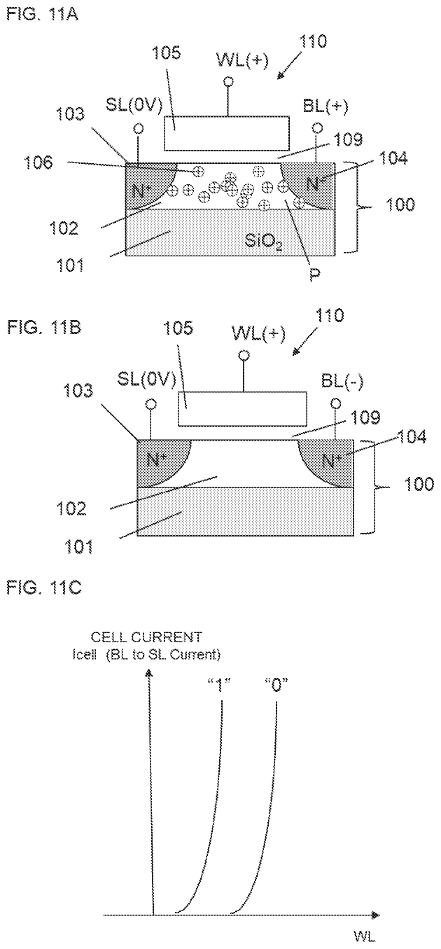

A method for producing dynamic flash memory of a fourth embodiment will be described with reference to FIGS. 8AA to 8AC and 8BA to BBC. Among the drawings, FIGS. 8AA and 8RA are plan views, FIGS. 8AB and 8BB are cross-sectional views along line X-X′ in FIGS. 8AA and 8BA, and FIGS. 8AC and 8BC are cross-sectional views along line Y-Y′ in FIGS. 8AA and 8BA.

As illustrated in FIGS. 5DA to 5DC, the SiGe layer 23 is formed on the TiN layer 18. Then, as illustrated in FIGS. 8AA to 8AC, a portion of the HfO₂ layer 17 at a level above the SiGe layer 23 in the vertical direction is removed to form a HfO₂ layer 17a.

Next, as illustrated in FIGS. 8BA to 8BC, the exposed side faces of the Si pillars 12a to 12d are oxidized to form thin SiO₂ layers 42a, 42b, 42c, and 42d. At the same time, the SiGe layer 23 is oxidized to form a SiO₂ layer 43. When only the upper layer of the SiGe layer 23 is oxidized through such oxidation, a SiGe layer 23c remains as the lower layer. Then, a HfO₂ layer 44 is deposited on the entire surface. Thereafter, the steps in FIGS. 5FA to 5JC are performed to form dynamic flash memory on the substrate 10. Herein, each of the SiO₂ layers 42a to 42d and the HfO₂ layer 44 surrounding the Si pillars 12a to 12d serves as the gate insulating layer.

The present embodiment has the following features.

### Feature 1

In the third embodiment, the SiO₂ layer 23a and the SiO₂ layers 40a to 40d are separately formed. In contrast, in the present embodiment, the SiO₂ lavers 40a to 40d and the SiO₂ layer 23c are formed at the same time. As in the third embodiment, when the SiO₂ layers 40a to 40d are formed after the SiO_{y} layer 23c has been formed, a cleaning step is needed. This causes the SiO₂ layer 23c to be etched. In such a case, uniform etching is required across the entire wafer. In contrast, the present embodiment is free from such a problem.

### Feature 2

In the present embodiment also, even when the SiGe layer 23c remains as illustrated in FIGS. 8BA to 8BC, no problem arises regarding the electrically insulated state of the TiN layer 18 and the TiN layers 26a and 26b. Accordingly, in the present embodiment, insulation between the TiN layer 18 and the TiN layers 26a and 26b can be easily achieved.

### Other Embodiments

Although the Si pillars 2 and 12a to 12d are formed in the present invention, it is also possible to form semiconductor pillars of a semiconductor material other than Si. This is also true of the other embodiments according to the present invention.

Each of the N⁺ layers 3a, 3b, 11, and 13 in the first embodiment may also be formed of a layer of Si or other semiconductor materials containing donor impurities. In addition, the N⁺ layers 3a, 3b, 11, and 13 may be formed of lavers of different semiconductor materials. The N⁺ layers may be formed using the epitaxial crystal growth method or other methods. This is also true of the other embodiments according to the present invention.

As the mask material layers 14a to 14d illustrated in FIGS. 5AA to 5AC, it is also possible to use other single-layer or multilayer' material layers containing organic materials or inorganic materials as long as such materials are suitable for implementing the present invention, such as a SiO₂ layer, an aluminum oxide (also referred to as Al₂O₃ or AlO) layer, or a SiN layer, for example. This is also true of the other embodiments according to the present invention.

The thickness and shape of each of the mask material layers 14a to 14d illustrated in the first embodiment will change in the course of the following polishing through CMP, RIE etching, and cleaning. Such changes are acceptable as long as they do not obstruct the implementation of the present invention. This is also true of the other embodiments according to the present invention.

In FIG. 1, the first gate conductor layer 5a connects to the plate line PL, and the second gate conductor layer 5b connects to the word line WL. In contrast, the first gate conductor layer 5a may connect to the word line WL, and the second gate conductor layer 5b may connect to the plate line PL. In such a case, the length of the second gate conductor layer 5b in the vertical direction is desirably set greater than the length of the first gate conductor layer 5b in the vertical direction. In addition, in FIGS. 5AA, to 5K, the order of forming the TiN layers 26a and 26b and the TiN layer 18 may be reversed. This also allows for a normal operation of the dynamic flash memory. This is also true of the other embodiments according to the present invention.

In FIGS. 5GA to 5GC, the upper end positions of The mask material layers 27a and 27b are set at the same level as the upper end positions of the mask material layers 14a to 14d. In contrast, the upper ends of the mask material layers 27a and 27b in the vertical direction may be at the level of the side faces of the mask material layers 14a to 14d as long as the conditions for covering the side faces of the N⁺ layers 13a to 13d are satisfied in the RIE step. This is also true of the other embodiments according to the present invention.

In the first embodiment, the TiN layer 18 is used as the plate line PL and the gate conductor layer 5a connecting to the plate line PL. In contrast, it is also possible to use a single conductor material layer or multiple conductor material layers combined together instead of the TiN layer 18. Likewise, the TiN layers 26a and 26b are used as the word lines WL and the gate conductor layers 5b connecting to the respective word lines WL. In contrast, it is also possible to use a single conductor material layer or multiple conductor material layers combined together instead of each of the TiN layers 26a and 26b. In addition, the outer side of each gate TiN layer may connect to a wire metal layer of W, for example. This is also true of the other embodiments according to the present invention.

The SiN layers 27a and 27b illustrated in FIGS. 5GA to 5GC are etching mask layers for forming the TiN layers 26a and 26b, respectively. As the SiN layers 27a and 27b, it is also possible to use other single-layer or multilayer material layers as long as such layers have the functions of the etching masks of the present embodiment. This is also true of the other embodiments according to the present invention.

In the description of the first embodiment, the oxidation rate of the SiGe layer 23 is higher than that of Si (for example, see A. Veloso, et. al.: “Vertical Nanowire and Nanosheet FETs: Device Features, Novel Schemes for Improved. Process Control and Enhanced Mobility, Potential for Faster & More Energy Efficient Circuits” IEDM19 Digest Papers, pp.230-233, 2019). Accordingly, even without entirely oxidizing the SiGe layer 23 in FIGS. 5EA to 5EC, for example, it is possible to form the SiO₂ layer 23a by, before forming the HfO₂ layer 17b in FIGS. 5FA to 5FC, forming a thin SiO₂ layer on each of the side faces of the Si pillars 12a to 12d through thermal oxidation and promoting the oxidation of the SiGe layer 23 at the same time. This simplifies the process design for forming the SiO₂ layer 23a for insulating the TiN layer 18 and the TiN layers 26a and 26b as described above. This is also true of the other embodiments according to the present invention.

In the description of FIGS. 5JA to 5JC, the bit line conductor layer BL1 (32a) and the bit line conductor layer BL2 (32h) are formed in a single step. However, it is also possible to first form the inside of the contact holes 30a to 30d using first conductor layers, and then form conductor layers to serve as the bit line conductor layer BL1 and the bit line conductor layer BL2 such that they connect to the first conductor layers. This is also true of the other embodiments according to the present invention.

In the first embodiment, the N⁺ layer 11a on the outer periphery portions of the Si pillars 12a to 12d may have formed thereon a low-resistance conductor layer of tungsten (W) for example. In addition, a portion of the N⁺ layer 11a around the Si pillars 12a and 12b and that around the Si pillars 12c and 12d may be isolated from each other by STI (Shallow Trench Isolation), for example. This is also true of the other embodiments according to the present invention.

In FIG. 1, one or both of the first gate conductor layer 5a and the second gate conductor layer 5b may be divided into a plurality of layers in the horizontal or vertical direction. It is also possible to divide the first gate conductor layer 5a into two layers in the vertical direction, and provide the resulting two gate conductor layers on the opposite sides of the second gate conductor layer 5b. In such a case, the three gate conductor layers, which include the two gate conductor layers obtained by dividing the first gate conductor layer 5a and the second gate conductor layer 5b, may have the same length in the vertical direction. This is also true of the other embodiments according to the present invention.

in the first embodiment, the shape of each of the Si pillars 12a to 12d as seen in plan view is circular. However, the shape of each of the Si pillars 12a to 12d as seen in plan view may be circular, elliptical, or a shape elongated in one direction, for example. It is also possible to form Si pillars with different shapes as seen in plan view in a mixed manner in a logic circuit region, which is formed away from the region of the dynamic flash memory cells, in accordance with the logic circuit design. This is also true of the other embodiments according to the present invention.

in the first embodiment and the fifth embodiment, the source line SL is negative-biased during an erase operation so that holes in the channel region 7 functioning as the floating body FB are pulled out. However, it is also possible to perform an erase operation by negative-biasing the bit line BL instead of the source line SL, or negative-biasing the source line SL and the bit line BL. Alternatively, an erase operation may be performed under other voltage conditions. This is also true of the other embodiments according to the present invention.

The present invention can be implemented in various embodiments and modifications without departing from the broad spirit and scope of the present invention. In addition, each of the aforementioned embodiments only describes an example of the present invention and is not intended to limit the scope of the present invention. The aforementioned examples and modified examples can be combined as appropriate. Further, even if some of the components of the aforementioned embodiments are removed as needed, the resulting structure is within the technical idea of the present invention.

With the method for producing a memory device using pillar-shaped semiconductor elements according to the present invention, it is possible to obtain high-density and high-performance dynamic flash memory.

What is claimed is:

1. A method for producing a memory device using pillar-shaped semiconductor elements, the memory device being configured to perform each of a data write operation, a data read operation, and a data erase operation by controlling a voltage applied to each of a first gate conductor layer, a second Gate conductor layer, a first impurity region, and a second impurity region, the method comprising:
forming a first semiconductor pillar standing in an upright position on a substrate along a vertical direction;
forming a first gate insulating layer surrounding a side face of the first semiconductor pillar;
forming a first conductor layer surrounding a side face of the first gate insulating layer;
forming a first oxidized insulating layer on the first conductor layer through oxidation;
forming a second gate insulating layer on the side face of the first semiconductor pillar at a level above the first oxidized insulating layer in the vertical direction;
forming the second gate conductor layer surrounding a side face of the second gate insulating layer;
forming the first gate conductor layer including the first conductor layer as a base material after forming the first conductor layer and before or after forming the first oxidized insulating layer;
forming the first impurity region connecting to a bottom portion of the first semiconductor pillar before or after forming the first semiconductor pillar; and
forming the second impurity region on top of the semiconductor pillar before or after forming the first semiconductor pillar.

2. The method for producing a memory device using pillar-shaped semiconductor elements according to claim 1, further comprising:
selectively forming a first material layer of a conductor or a semiconductor on the first gate conductor layer; and
oxidizing a surface layer or an entirety of the first material layer to form the first oxidized insulating layer.

3. The method for producing a memory device using pillar-shaped semiconductor elements according to claim 1, further comprising oxidizing a surface layer of the first conductor layer to form the first oxidized insulating layer.

4. The method for producing a memory device using pillar-shaped semiconductor elements according to claim 1, further comprising for the second gate insulating layer continuously on the side face of the first semiconductor pillar and on the first oxidized insulating layer in the vertical direction.

5. The method for producing a memory device using pillar-shaped semiconductor elements according to claim 2, further comprising:
exposing the side face of the first semiconductor pillar at a level above the first material layer after forming the first oxidized insulating layer; and
oxidizing the exposed side face of the semiconductor pillar to form the second gate insulating layer.

6. The method for producing a memory device using pillar-shaped semiconductor elements according to claim 2, further comprising:
exposing the side face of the first semiconductor pillar at a level above the first gate insulating layer; and
oxidizing the first material layer to form the first oxidized insulating layer, and also oxidizing the exposed side face of the semiconductor pillar to form a second oxidized insulating layer,
wherein the second oxidized insulating layer serves as the second gate insulating layer.

7. The method for producing a memory device using pillar-shaped semiconductor elements according to claim 6, further comprising:
forming a first insulating layer surrounding a side face of the second oxidized insulating layer and continuous with an upper surface of the first oxidized insulating layer after forming the second oxidized insulating layer,
wherein the second oxidized insulating layer and the first insulating layer form the second gate insulating layer.

8. The method for producing a memory device using pillar-shaped semiconductor elements according to claim 1, further comprising:
leaving the first gate insulating layer at a level above the first oxidized insulating layer in the vertical direction, and then forming the second gate conductor layer,
wherein the first gate insulating layer left at the level above the first oxidized insulating layer serves as the second Gate insulating layer.

9. The method for producing a memory device using pillar-shaped semiconductor elements according to claim 1, further comprising:
forming a second conductor layer surrounding the second gate insulating layer after forming the second gate insulating layer, the second conductor layer having an upper surface position located around a lower end of the second impurity region;
selectively forming a second material layer of a conductor or a semiconductor on the second conductor layer; and
oxidizing a surface layer or as entirety of the second material layer to form a second oxidized insulating.

10. The method for producing a memory device using pillar-shaped semiconductor elements according to claim 7 further comprising oxidizing a surface layer of the second conductor layer to form the second oxidized insulating layer.

11. The method for producing a memory device using pillar-shaped semiconductor elements according to claim 2, wherein the first material layer is formed of silicon germanium (SiGe).

12. The method for producing a memory device using pillar-shaped semiconductor elements according to claim 1, wherein:
a wire connecting to the first impurity region is a source line, a wire connecting to the second impurity region is a bit line, one of a wire connecting to the first gate conductor layer or a wire connecting to the second gate conductor layer is formed as a word line, and another is formed as a first drive control line, and
each of the data erase operation, the data read operation, and the data write operation is performed with a voltage applied to each of the source line, the bit line, the first drive control line, and the word line.

13. The method for producing a memory device using pillar-shaped semiconductor elements according to claim 1, wherein the first gate conductor layer, the first semiconductor pillar, and the second gate conductor layer are formed such that a first gate capacitance between the first gate conductor layer and the first semiconductor pillar is larger than a second gate capacitance between the second gate conductor layer and the first semiconductor pillar.

14. The method for producing a memory device using pillar-shaped semiconductor elements according to claim 1, wherein the first gate conductor layer, the second gate conductor layer, the first impurity region, and the second impurity region are formed so as to allow each of the data write operation and the data erase operation to be performed, the data write operation including retaining holes generated through an impact ionization phenomenon or generated using a gate induced drain leakage current in the first semiconductor pillar by controlling a voltage applied to each of the first gate conductor laver, the second gate conductor layer, the first impurity region, and the second impurity region, and the data erase operation including removing the holes from the first semiconductor pillar by controlling a voltage applied to each of the first gate conductor layer, the second gate conductor layer, the first impurity region, and the second impurity region.

15. The method for producing a memory device using pillar-shaped semiconductor elements according to claim 1, further comprising:
after forming the second gate conductor layer, forming a third gate insulating layer surrounding the side face of the first semiconductor pillar, and forming a second oxidized insulating layer on the second Gate conductor layer; and
forming a third gate conductor layer surrounding the third gate insulating layer.

16. The method for producing a memory device using pillar-shaped semiconductor elements according to claim wherein the first gate conductor layer, the second gate conductor layer, and the third gate conductor layer have the same length in the vertical direction.
